(19) United States
(12) Patent Application Publication
(10) Pub. No.: US 2021/0204745 A1
(43) Pub. Date: Jul. 8, 2021

(54) A KETTLE

(71) Applicant: BREVILLE PTY LIMITED, Alexandria (AU)

(72) Inventors: Con PSAROLOGOS, Bardwell Valley (AU); Xiang REN, Alexandria (AU)

(21) Appl. No.: 17/058,109

(22) PCT Filed: May 23, 2019
(86) PCT No.: PCT/AU2019/050505

§ 371 Date: Nov. 23, 2020

(30) Foreign Application Priority Data
May 23, 2018 (AU) 2018901801

(51) Int. Cl. A47J 27/21; H05B 1/02; H05K 1/02

(52) U.S. Cl. CPC A47J 27/21041; A47J 27/21166; H05K 2201/10416; H05K 1/0203; H05K 2201/10166; H05B 1/0202

(57) ABSTRACT

An appliance (10) to heat a liquid, the appliance (10) including: a hollow body (16) providing a chamber (23) to receive the liquid, the body (16) having a bottom wall (17) and a side wall (18) extending upwardly from the bottom wall (17) so as to surround the chamber (23); an electrical resistance heater (27) fixed to the body (16) and to which electric power is delivered so that the heater (27) has a raised temperature to heat the liquid contained in the chamber (23); a switch (29), adjacent the heater (27), that receives electric power and delivers electric power to the heater (27), the switch (29) being mounted in the body (16) and located so that heat generated by the switch (29) can be delivered to the liquid via conduction; and wherein the switch (29) is mounted on the body (16) to inhibit heat transfer by conduction between the heater (27) and switch (29).

### FIELD

The present invention relates to appliances to heat liquids, and more particularly, but not exclusively to electrically operated jugs and kettles.

### BACKGROUND

In domestic appliances such as kettles, a switch is employed to deliver electric energy to the heating element.

The above discussed switches are typically triac switches, and generate heat during operation.

These triac switches are attached to heat sinks to assist in dissipating heat energy generated by the switch. A disadvantage of this construction is that the heat sink is of considerable size. This results in portions of the jug or kettle being undesirably enlarged.

An additional disadvantage is that the heat is dissipated to atmosphere, and therefore is lost.

### OBJECT

It is the object of the present invention to overcome or substantially ameliorate at least one of the above disadvantages.

### SUMMARY OF INVENTION

There is disclosed herein an appliance to heat a liquid, the appliance including:

a hollow body providing a chamber to receive the liquid, the body having a bottom wall and a side wall extending upwardly from the bottom wall so as to surround the chamber;

an electrical resistance heater fixed to the body and to which electric power is delivered so that the heater has a raised temperature to heat the liquid contained in the chamber;

a switch, adjacent the heater, that receives electric power and delivers electric power to the heater, the switch being mounted in the body and located so that heat generated by the switch can be delivered to the liquid via conduction; and wherein

the switch is mounted on the body to inhibit heat transfer by conduction between the heater and switch.

Preferably, the heater and switch are mounted in the bottom wall, with the appliance further including an insulating member located between the switch and the bottom wall to inhibit the transfer of heat by conduction between the bottom wall and the switch.

Preferably, the insulating member is a seal, sealingly connecting the switch with the base.

Preferably, the appliance further includes a heat sink, with the switch being mounted to the heat sink, and wherein the bottom wall has an aperture, into which the heat sink projects, so as to be exposed to said liquid.

Preferably, the heater is mounted on a board, with the board having an aperture into which the heat sink or switch projects.

Preferably, the switch is mounted on the bottom wall.

In an alternative preferred form, the switch and the heater are mounted on a board, with the board having an area of reduced thickness surrounding the switch to at least inhibit the transfer of heat by conduction from the heater to the switch.

### BRIEF DESCRIPTION OF DRAWINGS

Preferred forms of the present invention will now be described by way of example with reference to the accompanying drawings wherein:

FIG. 1 is a schematic sectioned side elevation of a kettle;

FIG. 2 is a schematic enlarged view of the portion 2 identified in FIG. 1;

FIGS. 3 to 7 are schematic sectioned side elevations of modifications of the portion 2 of the kettle of FIG. 1; and

FIG. 8 is a schematic plan view of a printed circuit board employed in the kettle of FIG. 1.

### DESCRIPTION OF EMBODIMENTS

In the accompanying drawings there is schematically depicted an appliance to heat water, preferably the appliance is a kettle 10. The kettle 10 includes a jug 12 and a base 11 upon which the jug 12 rests. The base 11 delivers electric power to the jug 12.

The base 11 includes a power supply 13 that is electrically coupled to the jug 12 when the jug 12 is resting on the base 11. In particular, the base 11 is provided with a plurality of electrical cables and contacts 14 that are engaged by electrical cables and contacts 15 of the jug 12, so that the base 11 is operable to provide the jug 12 with electric power for heating water contained in the jug 12.

The power supply 13 includes a micro-processor 47, and a power inlet 48.

Cooperating with the micro-processor 47 is a user interface 49, that is operated to control the micro-processor 47. The series of cables and contacts 14 and 15 provide for the delivery of power to the switch 29, as well as signals from the temperature sensor 51. The signals are delivered to the micro-processor 47 for the purposes of control, including temperature control.

The jug 12 includes a hollow body 16. The body 16 includes a bottom wall 17 from which there upwardly extends a side wall 18, with the side wall 18 providing a pouring lip 19 and a rim 20. The rim 20 surrounds an upper opening 21 that is closed by a lid 22.

The bottom wall 17, side wall 18 and lid 22 enclose a chamber 23 that is to receive the water to be heated.

The jug 12 also includes a stand 24 fixed to the bottom wall 17 and upon which the jug 12 rests.

To heat the water in chamber 23, the jug 12 is provided with a heater assembly 25 that electrically coupled to the contacts 15 so as to receive electric power therefrom. The assembly 25 includes a printed circuit board 26, to which there is applied a heating element 27. In this embodiment the heating element 27 is a resistive track, that is a low thermos mass heater.

Via a connection 28 the heating element 27 receives power from a switch 29, that in this embodiment is triac switch.

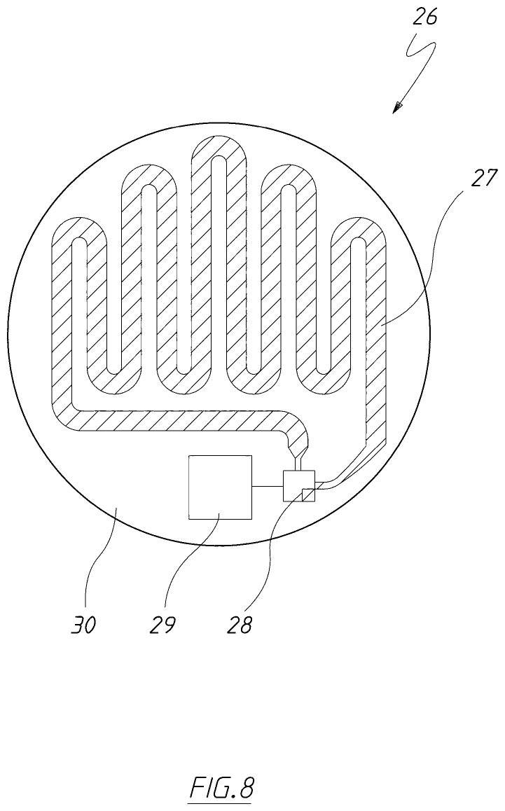

In the embodiment of FIG. 8, and as also illustrated in FIG. 4, the switch 29 is mounted on the board 30 of the printed circuit board 26. However, heat transfer between the heating element 27 and the switch 29 is inhibited by an area 31 of reduced thickness of the board 30, the area 31 surrounds the switch 29. Due to the reduced thickness of the board 30, heat from the element 27 is inhibited being transferred, by conduction, to the switch 29. In the other embodiments the switch 29 is not mounted on the board 30.

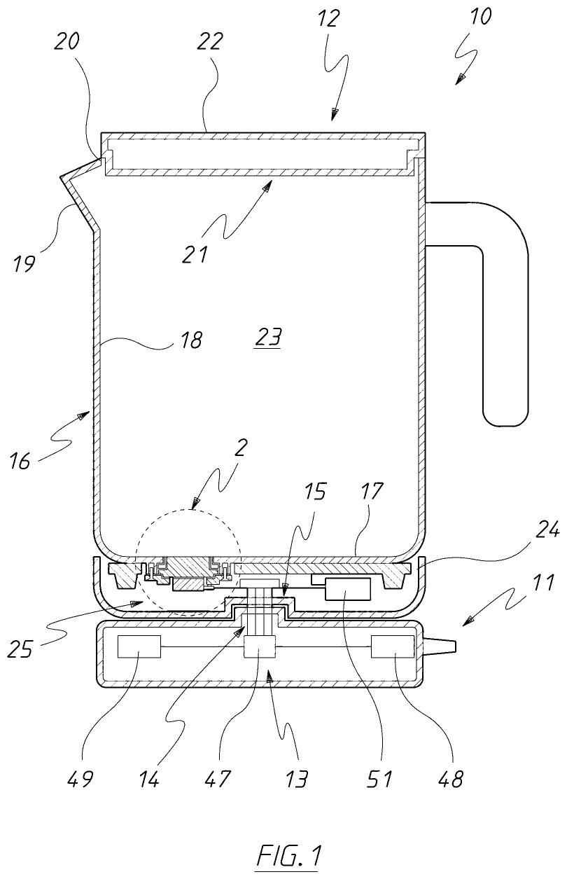

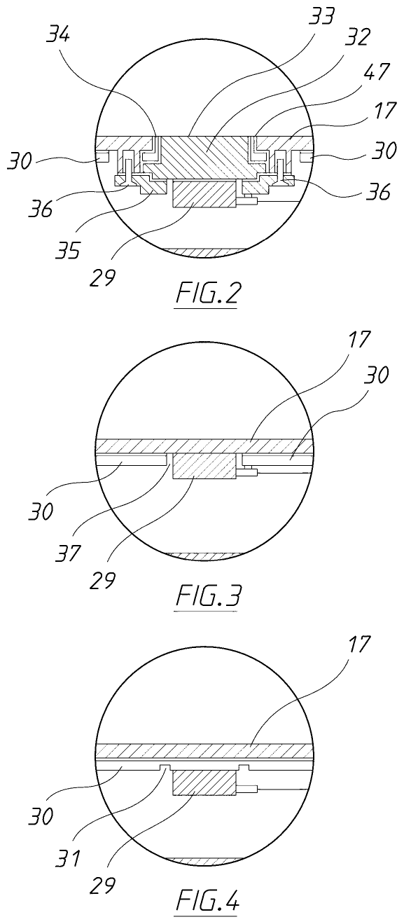

In the embodiment of FIGS. 1 and 2, the switch 29 is fixed to a heat sink 32 that has a surface 33 exposed to the water in the chamber 23. The heat sink 32, via conduction, receives heat from the switch 29, and transfers the heat to the water via the surface 33.

The heat sink 32, and therefore the switch 29, is inhibited from receiving heat, via conduction, from the element 27, via the bottom wall 17, by a seal 34 that is “sandwiched” between the bottom wall 17 and heat sink 32.

A bracket 35, via threaded fasteners 36, fixes the heat sink 32 and seal 34 to the bottom wall 17. The heat sink 32 is maintained in an aperture 47 in the bottom wall 17.

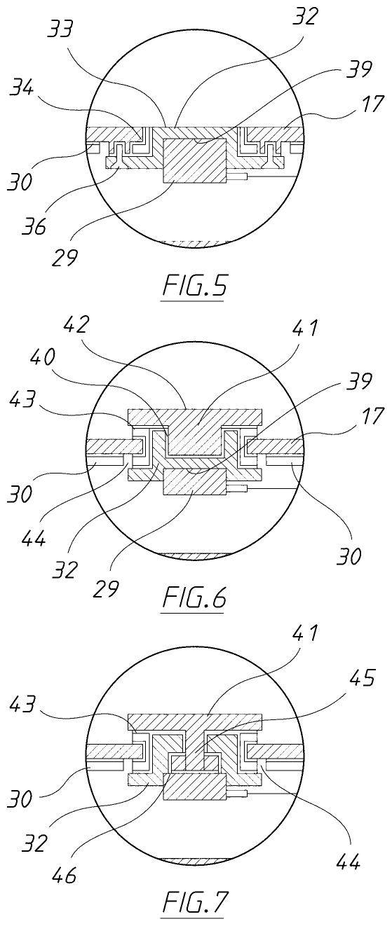

In the embodiment of FIG. 3, the switch 29 is fixed directly to the bottom wall 17. However, the switch 29 is at least partly conductive isolated from the board 30 by a gap 37 between the board 30 and the heat sink 32.

In the embodiment of FIG. 5, the switch 29 is directly mounted in a cavity 39 in the heat sink 32, with the heat sink 32, like the previous embodiment, having a surface 33 exposed to the water being heated.

Like the embodiment of FIG. 2, a seal 34 aids in thermally isolating the heat sink 32, and therefore the switch 29, from heat being conducted from the heating element 27 on the board 30, as well as heat transferred to the bottom wall 17.

In the embodiment of FIG. 6, the heat sink 32 again receives the switch 29 in a cavity 39, however, the heat sink 32 has a further cavity 40 that receives a heat sink cap 41 that has a surface 42 exposed to the water, to aid in cooling the heat sink 32 and therefore the switch 29. Again, the heat sink 32 and cap 41 are mounted in the bottom wall 17 by means of a seal 43, again to aid in thermally isolating the switch 29 from heat transferred via conduction, from the heating element 27.

A gap 44 surrounds the heat sink 32 again aid in thermally isolating the switch 29 conductively from heat being generated by the element 27.

In the embodiment of FIG. 7, the cap 41 has a threaded shaft 45 engaged by a nut 46 to secure the cap 41 to the heat sink 32.

The above described preferred embodiments have a number of advantages including inhibiting the transmission of heat, by conduction, from the heating element 27 to the switch 29.

A further advantage of the above described preferred embodiments is that water in the jug 12 receives heat from the switch 29 so that the heat is not lost, and the switch 29 temperature is controlled.

1. An appliance to heat a liquid, the appliance including:
a hollow body providing a chamber to receive the liquid, the body having a bottom wall and a side wall extending upwardly from the bottom wall so as to surround the chamber;
an electrical resistance heater fixed to the body and to which electric power is delivered so that the heater has a raised temperature to heat the liquid contained in the chamber;
a switch, adjacent the heater, that receives electric power and delivers electric power to the heater, the switch being mounted in the body and located so that heat generated by the switch can be delivered to the liquid via conduction; and wherein
the switch is mounted on the body to inhibit heat transfer by conduction between the heater and switch.

2. The appliance of claim 1, wherein the heater and switch are mounted in the bottom wall, with the appliance further including an insulating member located between the switch and the bottom wall to inhibit the transfer of heat by conduction between the bottom wall and the switch.

3. The appliance of claim 2, wherein the insulating member is a seal, sealingly connecting the switch with the bottom wall.

4. The appliance of any one of claims 1 to 3, further including a heat sink, with the switch being mounted to the heat sink, and wherein the bottom wall has an aperture, into which the heat sink projects, so as to be exposed to said liquid.

5. The appliance of claim 4, wherein the heater is mounted on a board, with the board having an aperture into which the heat sink or switch projects.

6. The appliance of claim 1, wherein the switch is mounted on the bottom wall.

7. The appliance of claim 6, wherein the switch and the heater are mounted on a board, with the board having an area of reduced thickness surrounding the switch to at least inhibit the transfer of heat by conduction from the heater to the switch.
